(19) United States
(12) Patent Application Publication
(10) Pub. No.: US 2010/0194413 A1
(43) Pub. Date: Aug. 5, 2010

(54) METHOD OF DETERMINING AN IMPEDANCE FUNCTION OF A LOUDSPEAKER

(75) Inventors: Klas Åke Dalbjörn, Billdal (SE); Kim Rishøj Pedersen, Ega (DK)

Correspondence Address: CANTOR COLBURN, LLP, 20 Church Street, 22nd Floor, Hartford, CT, 06103, US

(73) Assignee: LAB.GRUPPEN AB, Kungsbacka (SE)

(21) Appl. No.: 12/669,557

(22) PCT Filed: Jul. 16, 2007
(86) PCT No.: PCT/DK07/50099

§ 371 Date: Jan. 18, 2010

(51) Int. Cl. G01R 27/08

(52) U.S. Cl. 324/713

(57) ABSTRACT

The invention relates to a method of determining an impedance function IF of a load LS driven by an amplifier AM, said method comprising the steps of providing a digital audio signal DAS to said amplifier AM, measuring one of either a current signal representation CSR of current provided to said load LS by said amplifier AM or a voltage signal representation VSR of voltage provided to said load LS by said amplifier AM, determining a digital signal representation DSR on the basis of said digital audio signal DAS, and determining said impedance function IF of said load LS on the basis of said digital signal representation DSR and said measured one of either said current signal representation CSR or said voltage signal representation VSR. The invention further relates to a load monitoring amplifier comprising amplification means AM comprising an amplifier input AI for receiving a digital audio signal DAS and an amplifier output AO for delivering an amplified signal to a load LS and an analog reading point AR establishing one of either a current signal representation CSR by measuring the current of said amplified signal delivered to said load LS or a voltage signal representation VSR by measuring the voltage of said amplified signal delivered to said load LS, said load monitoring amplifier further comprising a digital reading point DR for determining a digital signal representation DSR on the basis of said digital audio signal DAS and a monitoring means MM for determining an impedance function IF of said load LS on the basis of said digital signal representation DSR and said one of either said current signal representation CSR or said voltage signal representation VSR.

### FIELD OF THE INVENTION

The present invention relates to determining the impedance function of a loudspeaker.

### BACKGROUND OF THE INVENTION

Knowledge of the impedance function of a loudspeaker connected to an amplifier can be used for several purposes, and hence determination thereof is desirable. When knowing the impedance function it is possible to, e.g., perform compensating equalization, adjust limiters, avoid providing damaging power to the loudspeaker, etc. Furthermore, live monitoring of the impedance function can be used to track temperature changes in the loudspeaker components, monitor the wear and aging of the loudspeaker, etc.

Conventional methods disclosed in the prior art comprises measuring the voltage and current at the power output of the amplifier, and calculating the impedance function from these two measurements. An amplifier comprising such measuring and calculating means is described in U.S. Pat. No. 5,719,526, where voltage and current are measured at the power output signal, converted into digital representations, and an impedance function calculated by a digital signal processor.

In some amplifier implementations it may however be a problem or at least an unnecessary cost to provide high-quality A/D-converters in order to be able to process the measurements in the digital processing means. On the other hand, it is impossible to implement contemporary, fast and high-resolution impedance function calculation and analysis thereof in the analog domain. Another issue is that because of the delays in the forward path of contemporary amplifiers, it may in some cases be impossible to react in time on an extreme measurement performed at the end of the path, because of the parts of the signal that has already been provided to the amplifier path from the processing means.

An object of the present invention may therefore be to reduce the amount of analog components, e.g. A/D-converters, needed in order to calculate an impedance function of a load connected to an amplifier.

An object of the present invention may be to improve the centralization in a contemporary amplifier comprising both digital and analog components.

An object of the present invention may be to estimate a representation of the output of an amplifier prior to its actual production and sufficiently early to perform critical actions on the basis thereof.

### SUMMARY OF THE INVENTION

The present invention relates to a method of determining an impedance function IF of a load LS driven by an amplifier AM, said method comprising the steps of providing a digital audio signal DAS to said amplifier AM,

measuring one of either a current signal representation CSR of current provided to said load LS by said amplifier AM or a voltage signal representation VSR of voltage provided to said load LS by said amplifier AM,
determining a digital signal representation DSR on the basis of said digital audio signal DAS, and
determining said impedance function IF of said load LS on the basis of said digital signal representation DSR and said measured one of either said current signal representation CSR or said voltage signal representation VSR.

According to the present invention is provided a method whereby impedance function calculation of a load can be performed by only one analog measurement and converter, i.e. the current measurement for a traditional amplifier or a voltage measurement for a current amplifier, thereby saving an expensive high-quality and fast A/D-converter solution.

Furthermore the present invention facilitates knowledge of the output signal amplitude, or current for a current amplifier, before it actually happens at the output, because there is a considerable delay in the amplifier means, in particular if it comprises an A/D-converter, causing the digital signal representation DSR to be established up to e.g. 1 ms before its corresponding power amplified analog representation is produced at the amplifier output.

Moreover, the present invention facilitates a direct, digital connection between the digital audio signal and the signal processing applied to that, and the digital impedance calculating circuitry. Thereby is facilitated using a single digital signal processor or other suitable digital processing means for both purposes. If distributed processing is desired, the present invention facilitates avoiding input from the analog domain in an even higher degree than previously known.

When said method is carried out during operation of said amplifier AM, an advantageous embodiment of the present invention is obtained.

According to a very preferred embodiment of the present invention, the impedance function of the load can be determined at any time, even during normal use with an arbitrary input signal just fulfilling a few criteria regarding its frequency spectrum.

When said step of determining said impedance function IF is performed by digital signal processing means MM, DSP, an advantageous embodiment of the present invention is obtained

When said measured one of either said current signal representation CSR or said voltage signal representation VSR is converted into a digital representation by means of an analog-to-digital converter ADC, an advantageous embodiment of the present invention is obtained.

When said method comprises adding a delay to said digital signal representation DSR in order to establish synchrony between said determined digital signal representation and said measured current signal representation, an advantageous embodiment of the present invention is obtained.

In a very preferred embodiment of the present invention a delay is applied to the digital signal representation in order to avoid determining an impedance function on the basis of signals that are not synchronized and would therefore cause the result to be invalid. It is noted that the delay, within the scope of the present invention, may be applied at any suitable step in the processing chain, e.g. at the digital reading point, in the impedance calculation circuit ICP, etc. If implemented in the impedance calculation circuit, it could merely be established by means of a buffer of a suitable length on the digital signal representation input.

When said delay comprises a delay corresponding to a delay of said amplifier AM and a delay of said analog-to-digital converter ADC, an advantageous embodiment of the present invention is obtained.

When said method comprises a step of performing compensation signal processing of said digital signal representation DSR, an advantageous embodiment of the present invention is obtained.

In a preferred embodiment of the present invention, compensation processing is applied to the digital signal representation, in order to establish a signal that better resembles the output signal of the amplifier in embodiments where the amplifier applies an error to the output signal in an area significant to the impedance function calculation.

When said compensation signal processing is performed in accordance with an amplification means model AMM comprising information about said amplifier AM, an advantageous embodiment of the present invention is obtained.

When said amplification means model AMM comprises information about the delay of said amplifier AM, an advantageous embodiment of the present invention is obtained.

When said amplification means model AMM comprises information about the DC gain of said amplifier AM, an advantageous embodiment of the present invention is obtained.

When said amplification means model AMM comprises information about the frequency-dependent delay of said amplifier AM, an advantageous embodiment of the present invention is obtained.

When said compensation signal processing is performed in accordance with an amplification means model AMM comprising information about an output impedance of said amplifier AM, an advantageous embodiment of the present invention is obtained.

According to an embodiment of the present invention, information about the amplifier's output impedance may e.g. comprise information about an output filter of said amplifier.

When said amplification means model AMM comprises information about the transfer function of said amplifier AM, an advantageous embodiment of the present invention is obtained.

When said amplification means model AMM comprises information about said amplifier AM for a predefined frequency band, preferably the audio band, an advantageous embodiment of the present invention is obtained.

When compensation signal processing is performed in accordance with an amplification means model AMM comprising information, e.g. DC resistance, impedance, etc., about a cable connecting said amplifier AM with said load LS, an advantageous embodiment of the present invention is obtained.

When said amplification means model AMM is calibrated on a regular basis, an advantageous embodiment of the present invention is obtained.

In a preferred embodiment, the amplification means model AMM is calibrated or verified on a regular basis in order to reflect variations and fluctuations of amplifier parameters in the impedance function calculation procedure. Any way of determining the variations or fluctuations, i.e. manually, semi-automatically or fully automatically, by means of test signals or “live” signals, etc., are within the scope of the present invention.

When said calibration of said amplification means model AMM is performed on the basis of voltage or current measurements at the output of said amplifier AM of a reproduced test signal at each start-up and/or at user-specified times, an advantageous embodiment of the present invention is obtained.

When said step of determining said digital signal representation DSR on the basis of said digital audio signal DAS comprises reading a digital value from a register or buffer, an advantageous embodiment of the present invention is obtained.

When said amplifier AM comprises a voltage amplifier, an advantageous embodiment of the present invention is obtained.

When said amplifier AM comprises a current amplifier, an advantageous embodiment of the present invention is obtained.

The present invention further relates to a load monitoring amplifier comprising amplification means AM comprising an amplifier input AI for receiving a digital audio signal DAS and an amplifier output AO for delivering an amplified signal to a load LS and an analog reading point AR establishing one of either a current signal representation CSR by measuring the current of said amplified signal delivered to said load LS or a voltage signal representation VSR by measuring the voltage of said amplified signal delivered to said load LS, said load monitoring amplifier further comprising a digital reading point DR for determining a digital signal representation DSR on the basis of said digital audio signal DAS and a monitoring means MM for determining an impedance function IF of said load LS on the basis of said digital signal representation DSR and said one of either said current signal representation CSR or said voltage signal representation VSR.

The present invention provides an advantageous amplifier that is able to determine the impedance function of a connected load on the basis of only one analog measurement. This is particularly advantageous in contemporary amplifiers with digital processing and often even so-called digital amplification (class-D amplifiers), as all of the information and processing means are available in the digital domain of the amplifier, except from a single analog measurement. Hence, it is possible with the amplifier of the present invention to only measure the output current for traditional voltage amplifiers, or the output voltage for current amplifiers, in order to determine the impedance function and all the information derivable when the impedance function is determined.

It should be noted that even though the amplifier input AI is said to receive a digital audio signal DAS, a product comprising an amplifier according to an embodiment of the present invention can evidently within the scope of the invention comprise inputs for analog signals, e.g. RCA-connectors, BNC-connectors, etc., followed by suitable A/D conversion means in order to establish a digital audio signal DAS. This is further described with reference to FIG. 2C below.

When said monitoring means MM comprises an analog-to-digital converter ADC to convert said one of said current signal representation CSR or said voltage signal representation VSR into a digital representation and an impedance calculation circuit ICP for determining said impedance function IF, an advantageous embodiment of the present invention is obtained.

When said monitoring means MM comprises delay means DM for adding a delay to said digital signal representation DSR, an advantageous embodiment of the present invention is obtained.

When said delay means comprises a delay corresponding to a delay of said amplification means AM and said analog-to-digital converter ADC, an advantageous embodiment of the present invention is obtained.

When said monitoring means MM comprises an amplification means model AMM in accordance with which the digital signal representation DSR is processed before used for impedance function determination, an advantageous embodiment of the present invention is obtained.

When said amplification means model AMM comprises information about said amplification means AM, such as delay, frequency dependent delay, DC-gain, frequency dependent gain, non-linearities, output impedance, transfer function, etc., an advantageous embodiment of the present invention is obtained.

When said amplification means model AMM comprises information, e.g. DC resistance, impedance, etc., about a cable connecting said amplification means AM with said load LS, an advantageous embodiment of the present invention is obtained.

When said load monitoring amplifier further comprises a signal processor SP for processing said digital audio signal DAS, and wherein said signal processor SP and said impedance calculation circuit ICP is comprised in a digital signal processor DSP or other digital processing means, an advantageous embodiment of the present invention is obtained.

When said load monitoring amplifier further comprises a digital register or buffer from which said digital signal representation DSR may be read on the basis of said digital audio signal DAS, an advantageous embodiment of the present invention is obtained.

When said amplifier AM comprises a voltage amplifier, an advantageous embodiment of the present invention is obtained.

When said amplifier AM comprises a current amplifier, an advantageous embodiment of the present invention is obtained.

An invention further relates to an amplifier compensation circuit AC comprising a filter with a transfer function resembling the reverse of the difference between the transfer function of a subsequent amplification means and a predefined transfer function.

When said filter is adjustable, an advantageous embodiment of the present invention is obtained.

An invention further relates to an amplifier comprising an amplification compensation circuit AC according to the above and an amplification means AM.

When said amplifier comprises monitoring means MM for determining an impedance function of a load LS connected to said amplifier and means for adjusting said filter on the basis of said impedance function, an advantageous embodiment of the present invention is obtained.

When said amplifier comprises means for determining the class of a load LS connected to said amplifier and means for adjusting said filter on the basis of information related to said class of said load LS, an advantageous embodiment of the present invention is obtained.

When said amplification means AM comprises an output filter OF, an advantageous embodiment of the present invention is obtained.

When said impedance function is determined according to a method of determining an impedance function according to any of the above or by means of a load monitoring amplifier according to any of the above, an advantageous embodiment of the present invention is obtained.

### THE DRAWINGS

The invention will in the following be described with reference to the drawings where

FIG. 1 illustrates an embodiment of the present invention,

FIG. 2A-2D illustrate different embodiments of signal processing in embodiments of the present invention,

FIG. 3A-3D illustrate different embodiments of amplification in embodiments of the present invention,

FIG. 4A-4B illustrate different embodiments of monitoring means in embodiments of the present invention,

FIG. 5 illustrates a preferred embodiment of the present invention,

FIG. 6 illustrates an embodiment of the present invention,

FIG. 7 illustrates an embodiment of an amplifier with an amplifier compensation circuit according to an embodiment of the present invention, and

FIG. 8 illustrates examples of transfer functions of an amplification means.

### DETAILED DESCRIPTION

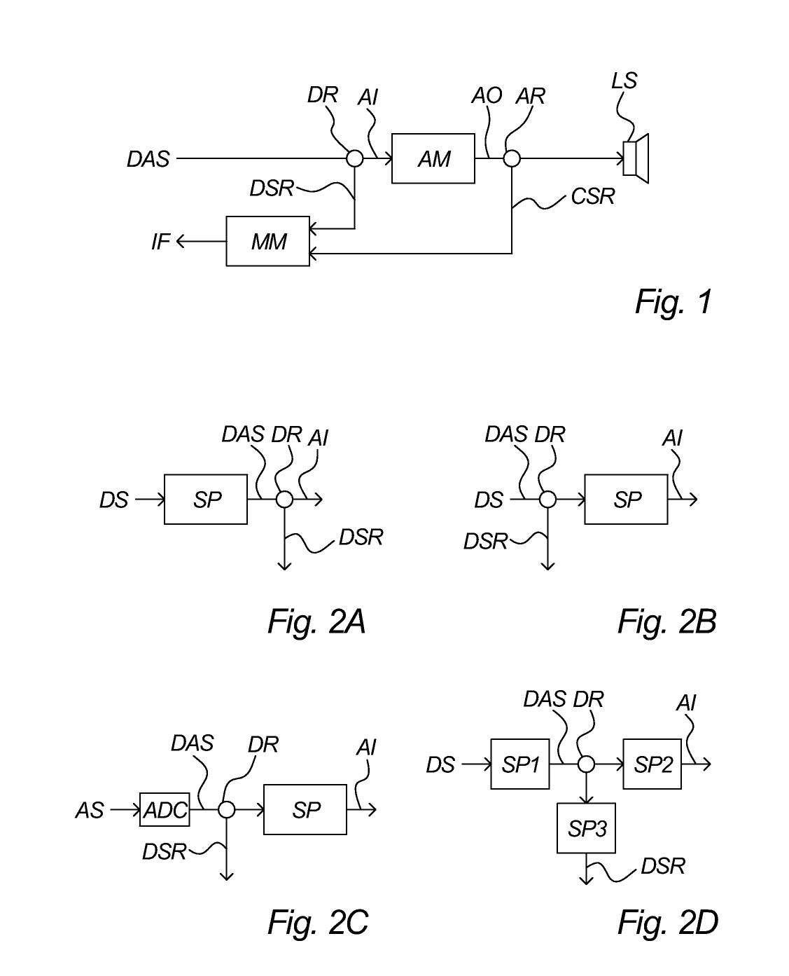

FIG. 1 illustrates an embodiment of the present invention. It comprises an amplification means AM for amplifying a digital audio signal DAS, which is provided at an amplifier input AI. An amplifier output AO is provided to a load or loudspeaker LS. The amplification means AM comprises within the scope of the present invention any kind of audio amplifier, as described in more detail below, and the digital audio signal DAS may within the scope of the present invention be provided in any suitable digital representation and by any suitable physical means, provided a suitable interface is implemented in the amplification means. The amplifier output AO is any signal suitable for distribution to a load or loudspeaker. It is mentioned that the conversion from the digitally represented input signal AI to the amplified output signal AO may be performed at any suitable point, and possibly even at several points, within the block labelled amplification means AM within the scope of the present invention. The load or loudspeaker LS may comprise any kind of load or loudspeaker suitable for connection to an amplifier output, including several loudspeakers coupled in parallel, 2-, 3-, or more way loudspeakers, etc. The load may further include non-ideal, i.e. real life, cabling, connectors, etc.

FIG. 1 further comprises a digital reading point DR for determining a digital signal representation DSR on the basis of the digital audio signal DAS. In some embodiments the digital signal representation DSR may be read from a register containing a current sample of the digital audio signal DAS, in a different embodiment the digital signal representation DSR may be read from a buffer containing several samples of the digital audio signal DAS, and in yet a different embodiment, the digital signal representation DSR may be established by splitting a data bus providing the digital audio signal DAS to the amplifier input AI. According to the present invention, any suitable implementation of the digital reading point DR is within the scope of the present invention, and the specific way of determining the digital signal representation DSR in a specific embodiment highly depends on the physical implementation of the digital audio signal DAS and does not affect the subject matter of the present invention.

FIG. 1 further comprises an analog reading point AR for measuring a current signal representation CSR of the current provided via the amplifier output AO to the load or loudspeaker LS by the amplification means AM. The analog reading point may comprise any suitable means for determining current. Numerous methods for current measurements are described in the prior art, and any method suitable for use at a sensitive, amplified audio signal, is within the scope of the present invention. The current signal representation CSR provided by most of the possible current measurement methods is an analog representation, but any representation is within the scope of the present invention.

FIG. 1 further comprises a monitoring means MM which receives the digital signal representation DSR and the current signal representation CSR, and, possibly among other things, establishes an impedance function IF on the basis of those representations. The monitoring means MM is described in more detail below.

To establish an impedance function associated with the loudspeaker is in principle needed measurements of the voltage and the current supplied to the loudspeaker. As described above, it is well-known to simply measure these representations at the amplifier output AO, convert them to digital signals, and calculate the impedance function by digital processing means. The present invention, however, requires with the embodiment of FIG. 1 only measurement of the current at the amplifier output signal. The signal voltage also required to determine the impedance function is derived from the digital audio signal input to the amplifier. Ideally, the amplification means AM comprises merely a gain, and the difference between the digital audio signal and the analog amplifier output is thus only a gain factor and the type of representation, digital vs. analog. As the impedance function is calculated by digital processing means, it is relevant to use the exact digital representation instead of a measured analog representation of the output voltage of the amplifier.

Even without knowing the gain of the amplification means, it is thereby possible to determine a relative or normalized impedance function on the basis of the digital signal representation DSR and an analog-to-digital converted version of the current signal representation CSR. A normalized impedance function suffices for several purposes, e.g. for frequency dependent impedance function analysis, recognition of impedance function characteristics and feature extraction, etc., which may, e.g., be used for identifying the type or model of loudspeaker, determining the temperature of internal loudspeaker components, etc.

In a more advanced embodiment of the present invention, the gain of the amplification means is known by the monitoring means MM, and it is thereby possible to determine the absolute impedance function of the loudspeaker. The absolute impedance function may be used for the same purposes as described above, and for further purposes requiring information about absolute impedances, e.g. for determining the number of loudspeakers coupled to the amplifier output AO in parallel.

In real amplifiers, the amplification means comprises not only a gain, but also a delay and a transfer function often causing less gain at in particular very low and very high frequencies. Also non-linear distortion exists to some, however low, degree in the amplification means. Hence, the presumption that a normalized or absolute impedance function can be calculated from the digital signal representation derived prior to the amplification means, is not true if a very accurate impedance function for in particular low and high frequencies is desired. In such cases, and depending on the degree of accuracy desired or required, the digital signal representation DSR may be processed before use in the impedance calculation to compensate for some of the above errors. Embodiments of the present invention covering this aspect are described in more detail below.

FIG. 2A-2D illustrate different implementations of the digital audio signal DAS and the digital reading point DR. In most audio amplifiers some degree and kind of signal processing is desired before the amplification, and essentially all contemporary amplifiers implement such signal processing by digital means, e.g. digital signal processors DSP's, microcontrollers or microprocessors, field programmable gate arrays FPGA's, application specific integrated circuits ASIC's, etc. The signal processing may, e.g., comprise equalization to compensate for known errors in the amplifier, output impedance, output filter, loudspeaker, cables or other components, limitation or compression to avoid distortion from clipping in the amplifier, filtering to, e.g., perform channel separation, signal delaying to improve cooperation with other amplifiers and taking physical distributions into consideration, etc. FIG. 2A-2D illustrate different implementation of such signal processing in an embodiment of the invention according to FIG. 1. It is noted, however, that any implementation of signal processing, including distributing the signal processing to several points, and/or analog signal processing, is within the scope of the present invention.

FIG. 2A illustrates an embodiment where the signal processor SP is implemented prior to the digital reading DR of the digital signal representation DSR. The signal processor SP is preferably a digitally implemented processor, e.g. inside a DSP or any other digital processing means as mentioned above, and it provides the digital audio signal DAS on the basis of a digital input signal DS.

FIG. 2B illustrates a different embodiment where the signal processor SP is implemented subsequently to the digital reading DR of the digital signal representation DSR. The signal processor provides the amplifier input AI on the basis of the digital audio signal DAS, derived from a digital input signal DS. The signal processor is preferably digitally implemented.

FIG. 2C illustrates yet a different embodiment with signal processing SP and digital reading DR arranged as in FIG. 2B, but with an analog input signal AS. An analog-to-digital converter ADC is provided for facilitating digital processing of the analog input signal, and for facilitating establishment of the digital audio signal DAS. In an alternative embodiment, the signal processing, or part of it, may be performed on the analog input signal AS, and the A/D-converter located subsequently, but prior to the digital reading point.

FIG. 2D illustrates a preferred embodiment where the digital signal representation DSR is derived from within the signal processor SP, i.e. where signal processing is or may be performed prior to the digital reading point by a first signal processor SP1, subsequent to the digital reading point by a second signal processor SP2 and optionally also by a third signal processor SP3 on the digital signal established by the digital reading point and from which the digital signal representation is derived. This embodiment facilitates using the signal processor for performing processing on the digital signal representation DSR instead of merely forwarding a copy of the digital audio signal DAS. It also facilitates a combination of the embodiments of FIGS. 2A and 2B, so that processing of the digital input signal DS can be done both before and after the digital reading point, i.e. basing the digital signal representation DSR on a partly processed digital audio signal. In this embodiment, the first signal processor SP1 will typically comprise shaping of the audio signal with regard to desired listening preferences, the second signal processor SP2 will typically comprise compensation of errors of the subsequent stages, e.g. the amplifier, output impedance, cable or loudspeaker in order to facilitate a true reproduction of sound, and the third signal processor SP3 will typically comprise processing needed to adapt the digital audio signal to a signal usable by the impedance calculation circuit.

It should be noted that any other implementation of signal processing and digital reading point, and any combination of the above-described features, is within the scope of the present invention.

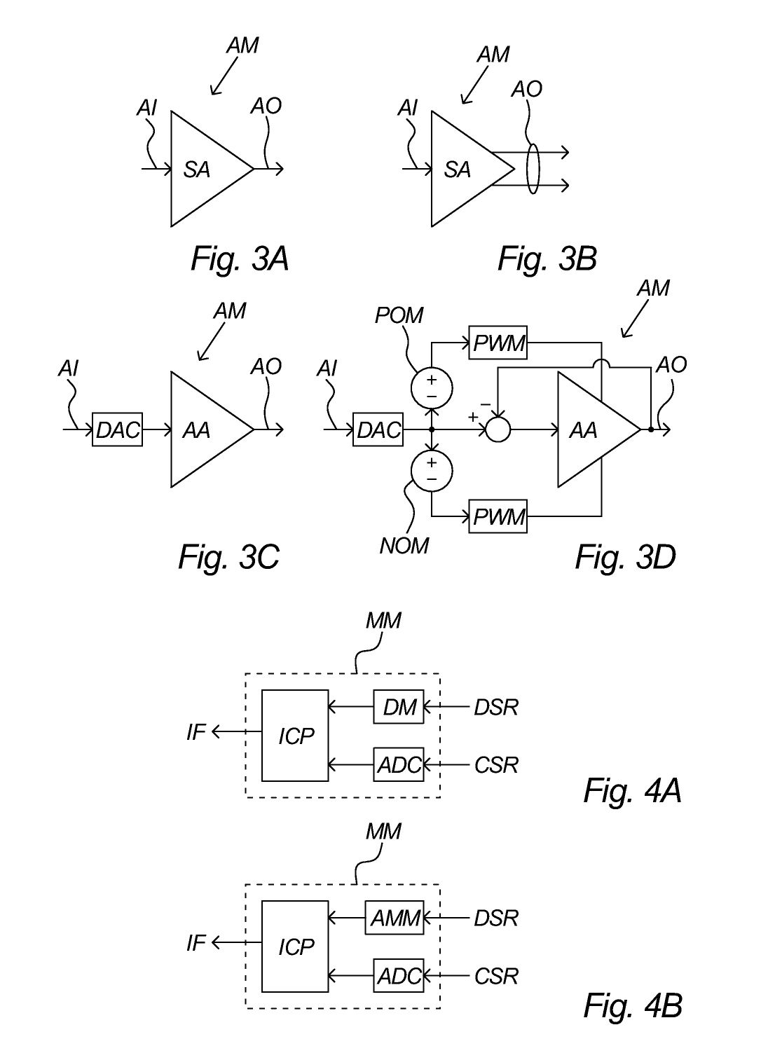

FIG. 3A-FIG. 3D illustrates different embodiments of amplification means AM according to the present invention. As mentioned above, any kind of audio amplifier implementing the amplification means AM is within the scope of the present invention.

FIG. 3A comprises a switching amplifier SA receiving the amplifier input AI and delivering the amplifier output AO. The switching amplifier may comprise any kind of switching amplifier implementation suitable for audio amplifiers, and preferably comprises at least a modulator for modulating the digital audio signal DAS at the amplifier input AI into a pulse width modulated signal, pulse density modulated signal or other suitable representation, which is then fed to a switching power stage. The output of the power stage is preferably demodulated, e.g. by means of an inductance-capacitance-implemented low-pass filter. Any specific implementation of the modulation and power stages is within the scope of the present invention, including self-oscillating PWM amplifiers, amplifiers with feedback, advanced modulation techniques comprising additional processing and error compensation, any kind of PWM modulation, e.g. 2-level, 3-level, etc., any kind of power stage, etc. In a preferred embodiment of FIG. 3A the modulation stage is digital and thus able to receive the digital audio signal DAS at the amplifier input AI. In alternative embodiments the pulse width modulation is performed in the analog domain and a D/A-converter is required for facilitating the digital audio signal input.

It should be noted that any representation or format of the amplifier output AO is within the scope of the present invention, e.g. single-ended or balanced outputs. FIG. 3B comprises an embodiment of the amplification means AM, comprising a switching amplifier SA as described above regarding FIG. 3A, but with a balanced amplifier output AO.

FIG. 3C illustrates an alternative embodiment of an amplification means AM, comprising a D/A-converter DAC and an analog amplifier AA. Any kind of analog amplifier is within the scope of the present invention, including any variations of, e.g. class B, class AB, class D, class H, class G, etc., amplifiers.

FIG. 3D illustrates a preferred embodiment of an amplification means AM for use in an embodiment of the present invention. It comprises a so-called class TD, or “tracked class D” amplifier, which utilizes an analog power stage AA supplied by switched power supplies controlled by the audio signal amplitude. A positive offset means POM establishes a control signal that has a value always a bit above the audio signal, and a negative offset means NOM establishes a control signal that has a value always a bit below the audio signal. These control signals are pulse width modulated by modulators PWM, and used as power supply for the analog amplifier AA, preferably a class AB amplifier. This implementation causes much less power loss in the analog power stage compared to a conventional class AB amplifier, as the transistors are only provided the required voltage for amplifying the actual audio signal. A D/A-converter DAC is provided for converting the digital audio signal

DAS into an analog audio signal for the analog power stage AA. FIG. 3D shows a feedback from the amplifier output AO to the input of the analog power stage for error suppression, but this feedback is optional. It is noted that the amplification means illustrated in FIG. 3D is described in much more detail, including a specific implementation thereof, in U.S. Pat. No. 5,200,711, hereby incorporated by reference.

It should be noted that any other amplification means implementation or combination of above-described features is within the scope of the present invention.

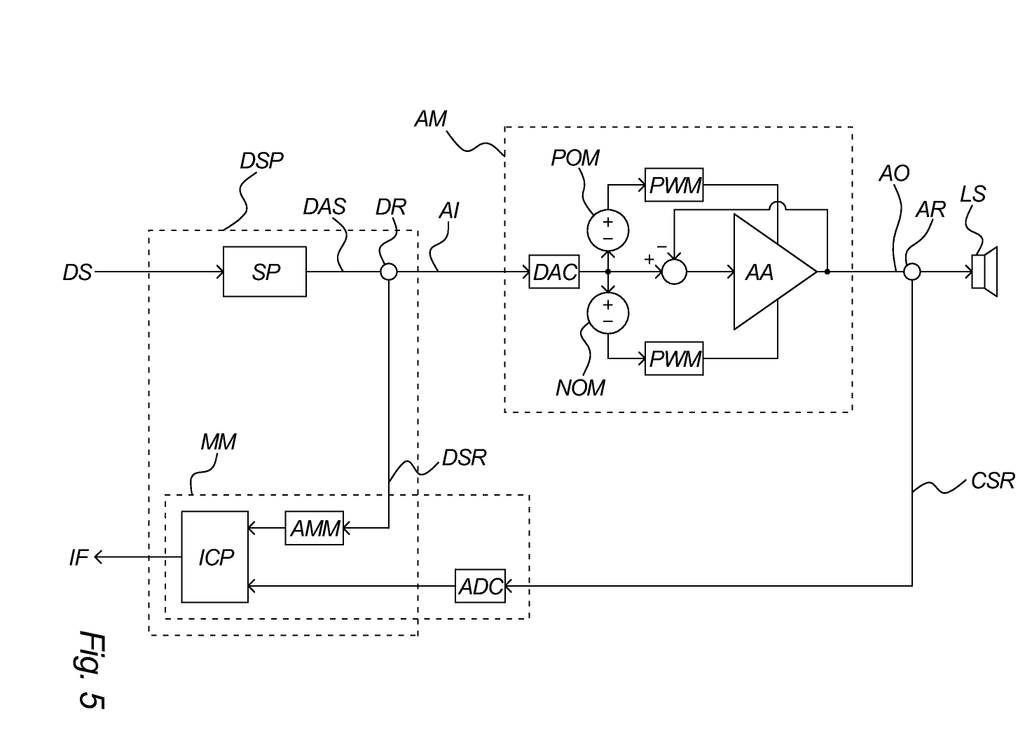

FIGS. 4A and 4B illustrates different embodiments of the monitoring means MM. FIG. 4A illustrates a monitoring means MM comprising an impedance calculation circuit ICP. The monitoring means receives the current signal representation CSR, which is converted to a digital representation by an A/D-converter ADC, and the digital signal representation DSR, which is delayed by delay means DM before provided to the impedance calculation circuit ICP. Because of the delay added to the audio signal by the amplification means AM, possibly comprising also a delay from a D/A-converter, and the delay added to the current signal representation by the A/D-converter, the digital signal representation derived from the digital audio signal DAS before entering the amplification means AM has to be delayed correspondingly in order to be in synchronism with corresponding current measurements derived from the audio signal subsequent to the amplification mean AM. In a preferred amplifier, the delay means DM may delay the signal by, e.g., 0.25-1.0 ms. Because of the delay means DM, the impedance calculation circuit ICP is able to calculate the impedance function IF on the basis of corresponding samples of digital signal value and analog output current, i.e. the analog output current caused by a certain digital signal value. If the accuracy requirement for the impedance function is not extremely high, and/or if the transfer function of the amplification means AM except for delay and DC gain is close to unity for the relevant frequencies, the embodiment of FIG. 4A may be sufficient to establish a useful impedance function IF.

In a more advanced embodiment, the delay means DM adds a frequency dependent delay, as the delay added to the audio signal by the amplification means is often frequency-dependent, i.e. is different for different frequencies.

FIG. 4B illustrates an embodiment of monitoring means MM which better takes into account additional errors added to the audio signal by the amplification means AM, and thereby it is necessary to add to the digital signal representation DSR to be able to calculate an impedance function that most accurately resembles the impedance function of the load, i.e. based on the signal that is provided to the load including the errors added by the amplification means AM. The improvement comprises the digital signal representation DSR being processed by an amplification means model AMM. This model ideally comprises the transfer function of the amplification means AM. As the full transfer function is in most real-life cases impossible to establish perfectly correct, even in the relevant frequency band, the amplification means model AMM may comprise the most significant errors caused by the amplification means AM, to a degree that facilitates calculation of a sufficiently accurate impedance function IF. Such significant errors preferably comprise the above-mentioned delay, preferably frequency dependent, the DC-gain, any frequency-dependent gain at low and high frequencies within the relevant band, and any significant non-linearities, e.g. frequency-dependent clipping values.

In a preferred embodiment of the invention, the amplification means model AMM is extended to also include a model of the loudspeaker cable, or significant errors related to the loudspeaker cable. In loudspeaker setups with relatively long cables the impedance of the cable, in particular it's DC resistance, becomes significant compared to the loudspeaker impedance, and will thus influence the impedance calculation significantly. A certain loudspeaker cable of 40 meters may for instance add a resistance of 1Ω (Ohm), and as the analog reading point AR in any practical case is located at the amplifier's end of the loudspeaker cable, the impedance function calculated will be an impedance function of the combined loudspeaker cable and loudspeaker. By compensating for the cable impedance in the extended amplification means model AMM, calculation of the loudspeaker impedance is facilitated, even with long, non-ideal cable connections.

The establishment of a cable model or an estimate of the most significant errors introduced by the cable may, e.g., be made by allowing the user to input cable characteristics such as cable length, cross section and resistivity into the processing means by means of a user interface. Alternatively, an amplifier with impedance calculation for example according to the present invention can be used to estimate the cable impedance by shorting the cable at the loudspeaker end during measuring, and subsequently establish a cable model to include in an extended amplification means model AMM from the measurements. Alternatively, as a neglected, significant cable resistivity will typically make a calculated impedance function indicate a very hot loudspeaker, the amplifier may provide a user interface means for providing to the processing means the information that the loudspeaker is definitely not hot, and the impedance features indicating a hot loudspeaker should instead be considered as cable impedance and, e.g., regarded as a cable model for subsequent measurements.

The amplification means model AMM may be established by measurements at the time of manufacture of the amplifier, or it may be configurable or adjustable in order to change with any changes of the amplification means AM over time. In an advanced embodiment, the transfer function, or significant characteristics thereof, of the amplification means is measured at each start-up or at user-defined times, and the result is used to calibrate the amplification means model AMM. For this purpose the amplifier may comprise means for measuring the voltage of the amplifier output signal, and an A/D-converter to provide this signal to the amplification means model AMM for calibration purposes. It is noted, however, that such voltage measurement does not require the same degree of quality, e.g. in regard to the A/D-converter, as if it is used for runtime impedance calculation as described in the prior art, as timing is not an important issue in a calibration situation.

In an advanced embodiment, the monitoring means further comprises means for analysing the digital signal representation, possibly after part of the amplification means model processing has been carried out, but before the delay has been added. Thereby is established a representation of the output signal, or at least the amplitude thereof, a considerable time, e.g. 0.25 or 1 ms, before it actually happens at the output. This time is sufficient to perform some degree of analysis and in case of critical results thereof, e.g. excessive power output, coarse clipping, etc., perform actions to avoid or reduce damage to the loudspeaker or unpleasant sound reproduction. The knowledge about the output signal before it happens could obviously also be used for non-critical purposes such as compensation, fine-tuning the signal processing, etc.

In yet an advanced embodiment, once the impedance function of the loudspeaker is calculated accurately, or when an accurate impedance function can be determined or established beforehand, it is possible to use the monitoring means for calculating the current of the amplifier output signal on the basis of the output voltage estimated from the digital signal representation, and the impedance function determined previously. Hence, it becomes possible to estimate both voltage and current of the power output signal before it actually happens and react accordingly. For this purpose, the current signal representation measurement and associated A/D-converter then become irrelevant.

In a preferred embodiment of the invention, the impedance calculation circuit ICP comprises windowing in the time domain of the input signals, and/or weighted averaging of the calculated impedance in order to establish a good estimate of the impedance function, and in order to avoid impedance functions calculated at uncertain signals or under uncertain conditions, e.g. during clipping, to influence the established impedance function significantly.

In a preferred embodiment, the impedance calculation circuit ICP comprises a multirate fast fourier transform FFT algorithm in order to establish impedance functions in relevant time windows, but any method of estimating or calculating an impedance function on the basis of the digital signal representation DSR and a voltage signal representation VSR or a current signal representation CSR is within the scope of the present invention.

FIG. 5 comprises a preferred embodiment of the present invention, established by combining the above-described preferred embodiments of sub-components. FIG. 5 further comprises centralization of all digital processing within one digital signal processor DSP. In an alternative embodiment, the digital processing is distributed to several digital signal processors or any other means for performing programmable or logical processing.

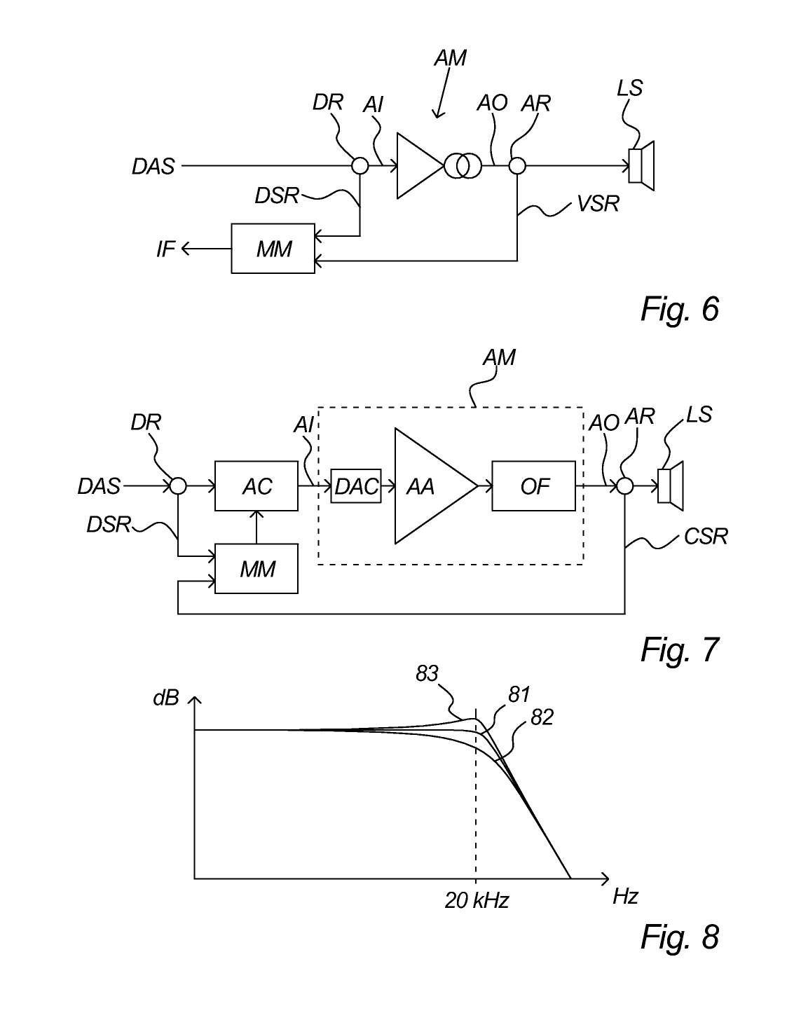

FIG. 6 illustrates a further alternative embodiment of the present invention. FIG. 6 corresponds to FIG. 1 except from the amplifier AM, which is a current amplifier in the embodiment of FIG. 6, and the signal measured by the analog reading point AR, which is a voltage signal representation VSR in the embodiment of FIG. 6.

The analog reading point AR is in the present embodiment of the invention measuring a voltage signal representation VSR of the voltage provided via the amplifier output AO to the load or loudspeaker LS by the current amplifier amplification means AM. The analog reading point may comprise any suitable means for determining voltage. Numerous methods for voltage measurements are described in the prior art, and any method suitable for use at a sensitive, amplified audio signal, is within the scope of the present invention. The voltage signal representation VSR provided by most of the possible voltage measurement methods is an analog representation, but any representation is within the scope of the present invention.

To establish an impedance function associated with the loudspeaker is in principle needed measurements of the voltage and the current supplied to the loudspeaker. As described above, it is well-known to simply measure these representations at the amplifier output AO, convert them to digital signals, and calculate the impedance function by digital processing means. The present invention, however, requires with the embodiment of FIG. 6, only measurement of the voltage at the current amplifier output signal. The signal current also required to determine the impedance function is derived from the digital audio signal input to the current amplifier on the basis of knowledge of the current gain and possibly also errors or transfer function of the current amplifier. As the impedance function is calculated by digital processing means, it is relevant to use the exact digital representation instead of a measured analog representation of the output current of the current amplifier.

Even without knowing the exact current gain of the current amplification means, it is thereby possible to determine a relative or normalized impedance function on the basis of the digital signal representation DSR and an analog-to-digital converted version of the voltage signal representation VSR. A normalized impedance function suffices for several purposes, e.g. for frequency dependent impedance function analysis, recognition of impedance function characteristics and feature extraction, etc., which may, e.g., be used for identifying the type or model of loudspeaker, determining the temperature of internal loudspeaker components, etc.

In a more advanced embodiment of the present invention, the gain of the amplification means is known by the monitoring means MM, and it is thereby possible to determine the absolute impedance function of the loudspeaker. The absolute impedance function may be used for the same purposes as described above, and for further purposes requiring information about absolute impedances, e.g. for determining the number of loudspeakers coupled to the amplifier output AO in parallel.

In real amplifiers, the current amplification means comprises not only a current gain, but also a delay and a transfer function often causing less current gain at certain frequency bands. Also non-linear distortion exists to some, however low, degree in the current amplification means. Hence, the presumption that a normalized or absolute impedance function can be calculated from the digital signal representation derived prior to the amplification means, is not true if a very accurate impedance function is desired. In such cases, and depending on the degree of accuracy desired or required, the digital signal representation DSR may be processed before use in the impedance calculation to compensate for some of the above errors. As a digital signal processor or likewise digital processing means are inherently available, it is possible to implement more advanced compensation processing for current amplifiers without additional circuitry or logics.

FIG. 7 illustrates a principle embodiment of an invention related to the above. It comprises an amplification means AM comprising a D/A-converter DAC, an analog amplifier AA and an output impedance OF. These blocks are in principle building blocks of any amplifier, and any distribution of the elements, any additional elements, and embodiments without a D/A-converter or with so-called digital amplifiers or no distinct output filter are within the scope of the invention. A typical aim when designing an amplification means AM is to establish a flat transfer function, i.e. a neutral transfer function plus gain in the audio band, but, depending on the type of amplification means, with attenuation of high frequency content, i.e. content above typically 20 kHz. A satisfactory transfer function is thus typically a low pass filter with a corner frequency of 20 kHz, as illustrated by reference sign 81 in FIG. 8. The transfer function referred to above may typically be the combined transfer function applied between the digital reading point DR and the analog reading point AR of FIG. 7. It should be noted that the above relates to conventional amplifiers without digital or analog reading points and amplifiers with only analog or digital reading points as well, and the reference to the digital and analog reading points in FIG. 7 are merely for the purpose of defining the transfer function.

Thus, a typical aim of an amplification means AM is to apply a transfer function as, e.g., illustrated in FIG. 8 by reference sign 81 in order to provide at the amplifier output AO an amplified, but otherwise unchanged version of the signal at the amplifier input. However, as the output filter impedance is typically significant in particular for high frequency content, and a connected load also resembles an impedance typically significant in particular for high frequency content, the output impedance OF and the load LS will in practice constitute a voltage divider, where the signal at the amplifier output depends on the relation between the output impedance OF and the load LS impedance.

In other words, it will typically not be possible to provide an output impedance OF or an amplification means AM that applies the same, ideal low pass transfer function 81 for any load LS. In FIG. 8 are shown possible transfer functions resulting from applying different loads. Whereas the ideal transfer function 81 may be achieved with a nominal load of e.g. 4Ω (Ohm), a different load with lower impedance, e.g. 2Ω (Ohm), which could be a 2Ω (Ohm) speaker or 2 parallel coupled 4Ω (Ohm) speakers may lead to a transfer function 82 between the amplifier input AI and amplifier output AO, and a different load with higher impedance, e.g. 8Ω (Ohm), may lead to a transfer function 83 between the amplifier input AI and amplifier output AO. Thus, a change of load impedance will typically change the amplification means AM transfer function. This is particularly significant when corresponding amplifiers drive loads with different impedances in a single setup, because the resulting output will differ due to the resulting different transfer functions. This is for example a problem with setups where some amplifier outputs are connected to 2 parallel coupled loudspeakers, whereas other equal amplifier outputs are connected to 4 parallel coupled, otherwise equal, loudspeakers, and the sound produced by the 2 amplifier outputs differs, in particular in the upper audio band.

The present invention related to FIG. 7 solves this problem by providing an amplifier compensation circuit AC prior to the amplification means AM or as part of the amplification means AM. The amplifier compensation circuit AC preferably comprises filtering that reverses the difference from ideal transfer function components applied by the amplification means AM. I.e. the amplification compensation circuit AC should evidently not reverse the complete act performed by the amplification means, but it should preferably apply a reverse of the difference between the desired transfer function 81 and the actual transfer function, e.g. 82 or 83, or any other errors introduced in the amplifier and incorrectly or not handled by the output filter or the amplification means in general.

The establishment of a suitable amplifier compensation circuit AC can initially be done by the amplification means manufacturer for a nominal load impedance. In a preferred embodiment, the amplifier compensation circuit AC is, however, adjustable or adaptive in order to automatically, semi-automatically or manually adapt to compensate for changes in the amplification means transfer function due to change in load impedance.

According to a preferred embodiment, a monitoring means MM according to the present invention described above is applied in order to establish an impedance function of the load. When knowing the impedance function of the load, the amplifier compensation circuit AC can be adapted to the resulting transfer function of the amplification means.

In an embodiment of the invention, the load impedance calculation and the adjustment of the amplifier compensating circuit AC have to be done iteratively because the adjusted amplifier compensating circuit AC also changes the impedance calculation regarding the load. In other words, as the transfer function of the amplification means and the impedance measured between the amplifier output AO over the load depends on each other, the adjustment of the compensation has to be done iteratively.

In an embodiment of the invention, the monitoring means MM comprises means for identifying the load or class of load on the basis of the calculated impedance or other load characteristics, or by means of user input, and on the basis of the then known load impedance the compensation circuit AC can be adjusted in one step.

In an embodiment of the invention, the amplifier compensation circuit AC is adapted to be a means by which the amplifier transfer function can be shaped to any desired form.

The present invention moreover facilitates using output filters in the amplification means which are tuned and optimized regarding noise attenuation or other purposes instead of the typical aim of establishing an ideal transfer function, as this problem is by the present invention handled in the amplifier compensation circuit.

1. Method of determining an impedance function of a load driven by an amplifier, said method comprising the steps of
providing a digital audio signal to said amplifier,
measuring one of either a current signal representation of current provided to said load by said amplifier a voltage signal representation of voltage provided to said load by said amplifier,
determining a digital signal representation on the basis of said digital audio signal, and
determining said impedance function of said load on the basis of said digital signal representation and said measured one of either said current signal representation or said voltage signal representation.

2. The method of determining an impedance function according to claim 1, whereby said method is carried out during operation of said amplifier.

3. The method of determining an impedance function according to claim 1, whereby said step of determining said impedance function is performed by a digital signal processor.

4. The method of determining an impedance function according to claim 1, whereby said measured one of either said current signal representation or said voltage signal representation is converted into a digital representation by means of an analog-to-digital converter.

5. The method of determining an impedance function according to claim 1, comprising adding a delay to said digital signal representation in order to establish synchrony between said determined digital signal representation and said measured current signal representation.

6. The method of determining an impedance function according to claim 5, whereby said delay comprises a delay corresponding to a delay of said amplifier and a delay of said analog-to-digital converter.

7. The method of determining an impedance function according to claim 1, comprising a step of performing compensation signal processing of said digital signal representation.

8. The method of determining an impedance function according to claim 7, whereby said compensation signal processing is performed in accordance with an amplification means model comprising information about said amplifier.

9. The method of determining an impedance function according to claim 8, whereby said amplification means model comprises information about the delay of said amplifier.

10. The method of determining an impedance function according to claim 8, whereby said amplification means model comprises information about the DC gain of said amplifier.

11. The method of determining an impedance function according to claim 8, whereby said amplification means model comprises information about the frequency-dependent delay of said amplifier.

12. The method of determining an impedance function according to claim 7, whereby said compensation signal processing is performed in accordance with an amplification means model comprising information about an output impedance of said amplifier.

13. The method of determining an impedance function according to claim 8, whereby said amplification means model comprises information about the transfer function of said amplifier.

14. The method of determining an impedance function according to claim 8, whereby said amplification means model comprises information about said amplifier for a predefined frequency band.

15. The method of determining an impedance function according to claim 7, whereby said compensation signal processing is performed in accordance with an amplification means model comprising information about a cable connecting said amplifier with said load.

16. The method of determining an impedance function according to claim 8, whereby said amplification means model is calibrated on a regular basis.

17. The method of determining an impedance function according to claim 16, whereby said calibration of said amplification means model is performed on the basis of voltage or current measurements at the output of said amplifier of a reproduced test signal at each start-up and/or at user-specified times.

18. The method of determining an impedance function according to claim 1, whereby said step of determining said digital signal representation on the basis of said digital audio signal comprises reading a digital value from a register or buffer.

19. The method of determining an impedance function according to claim 1, whereby said amplifier comprises a voltage amplifier.

20. The method of determining an impedance function according to claim 1, whereby said amplifier comprises a current amplifier.

21. Load monitoring amplifier comprising an amplifier comprising an amplifier input for receiving a digital audio signal and an amplifier output for delivering an amplified signal to a load and an analog reading point establishing one of either a current signal representation by measuring the current of said amplified signal delivered to said load or a voltage signal representation by measuring the voltage of said amplified signal delivered to said load, said load monitoring amplifier further comprising a digital reading point for determining a digital signal representation on the basis of said digital audio signal and a monitoring device for determining an impedance function of said load on the basis of said digital signal representation and said one of either said current signal representation or said voltage signal representation.

22. The load monitoring amplifier according to claim 21, wherein said monitoring device comprises an analog-to-digital converter to convert said one of said current signal representation or said voltage signal representation into a digital representation and an impedance calculation circuit for determining said impedance function.

23. The load monitoring amplifier according to claim 21, wherein said monitoring device comprises a delay unit for adding a delay to said digital signal representation.

24. The load monitoring amplifier according to claim 23, wherein said delay unit comprises a delay corresponding to a delay of said amplifier and said analog-to-digital converter.

25. The load monitoring amplifier according to claims 21, wherein said monitoring device comprises an amplification means model in accordance with which the digital signal representation is processed before used for impedance function determination.

26. The load monitoring amplifier according to claim 25, wherein said amplification means model comprises information about said amplifier.

27. The load monitoring amplifier according to claim 25, wherein said amplification means model comprises information about a cable connecting said amplification means with said load.

28. The load monitoring amplifier according to claim 21, further comprising a signal processor for processing said digital audio signal, and wherein said signal processor and said impedance calculation circuit is comprised in a digital signal processor or other digital process.

29. The load monitoring amplifier according to claim 21, comprising a digital register or buffer from which said digital signal representation may be read on the basis of said digital audio signal.

30. The load monitoring amplifier according to claims 21, wherein said amplifier comprises a voltage amplifier.

31. The load monitoring amplifier according to claim 21, wherein said amplifier comprises a current amplifier.

32. Amplifier compensation circuit comprising a filter with a transfer function resembling the reverse of the difference between the transfer function of a subsequent amplifier and a predefined transfer function.

33. The amplifier compensation circuit according to claim 32, wherein said filter is adjustable.

34. Amplifier comprising an amplification compensation circuit according to claim 32 and an amplifier.

35. The amplifier according to claim 34 comprising a monitoring device for determining an impedance function of a load connected to said amplifier and an adjustment unit for adjusting said filter on the basis of said impedance function.

36. The amplifier according to claim 34 comprising a classier for determining the class of a load connected to said amplifier and an adjustment unit for adjusting said filter on the basis of information related to said class of said load.

37. The amplifier according to claim 34, wherein said amplifier comprises an output impedance.

38. The amplifier according to claim 35, wherein said impedance function is determined according to a method of determining an impedance function or by means of a load monitoring amplifier,
wherein the method of determining an impedance function comprises the steps of providing a digital audio signal to said amplifier, measuring one of either a current signal representation of current provided to said load by said amplifier or a voltage signal representation of voltage provided to said load by said amplifier, determining a digital signal representation on the basis of said digital audio signal, and determining said impedance function of said load on the basis of said digital signal representation and said measured one of either said current signal representation or said voltage signal representation, and
wherein the load monitoring amplifier comprises an amplifier input for receiving a digital audio signal and an amplifier output for delivering an amplified signal to a load and an analog reading point establishing one of either a current signal representation by measuring the current of said amplified signal delivered to said load or a voltage signal representation by measuring the voltage of said amplified signal delivered to said load, said load monitoring amplifier further comprising a digital reading point for determining a digital signal representation on the basis of said digital audio signal and a monitoring device for determining an impedance function of said load on the basis of said digital signal representation and said one of either said current signal representation or said voltage signal representation.
